(19) United States
(12) Patent Application Publication
(10) Pub. No.: US 2008/0185712 A1
(43) Pub. Date: Aug. 7, 2008

(54) SEMICONDUCTOR DEVICE AND METHOD FOR MANUFACTURING THE SAME

(75) Inventors: Fujio Kanayama, Oita (JP); Tomoshi Ohde, Kanagawa-ken (JP); Mitsuru Adachi, Kanagawa (JP); Tetsunori Niimi, Kanagawa (JP); Hidetoshi Kusano, Oita (JP); Yuji Nishitani, Kanagawa (JP)

Correspondence Address: KATTEN MUCHIN ROSENMAN LLP, 575 MADISON AVENUE, NEW YORK, NY, 10022-2585, US

(73) Assignees: SONY CORPORATION, Tokyo (JP); SONY COMPUTER ENTERTAINMENT INC., Tokyo (JP)

(21) Appl. No.: 11/968,840

(22) Filed: Jan. 3, 2008

(30) Foreign Application Priority Data
Feb. 7, 2007 (JP) 2007-028494

(51) Int. Cl. H01L 23/36; H01L 21/56

(52) U.S. Cl. 257/712; 438/127; 257/E23.101; 257/E21.502

(57) ABSTRACT

A semiconductor device is provided in which the effect of the heat generated by a flip-chip mounted semiconductor on resin is suppressed. The semiconductor device includes: a substrate; a semiconductor chip which is mounted on the substrate with a front surface of the semiconductor chip facing downward; and a molding resin layer provided on a semiconductor chip-mounted surface of the substrate so as to be spaced apart from the semiconductor chip and to surround the semiconductor chip. In addition, the upper surface of the molding resin layer is positioned higher than the rear surface of the semiconductor chip.

### BACKGROUND OF THE INVENTION

1. Field of the Invention

The present invention relates to a semiconductor device having a semiconductor chip mounted on a substrate and to a method for manufacturing the same.

2. Description of the Related Art

In recent years, the size of electronic devices such as computers, cellular phones, and PDAs (Personal Digital Assistances) has been reduced, and the functionality and speed thereof has increased. Accordingly, there is a demand for a further reduction in the size and a further increase in the speed and density of semiconductor devices on which a semiconductor chip, such as an IC (integrated circuit) or an LSI (large scale integrated circuit), for such electronic devices is mounted. The reduction in the size and increase in the speed and density of semiconductor devices has resulted in an increase in power consumption, and therefore the amount of heat generated per unit volume tends to increase. Accordingly, operational stability has become an issue. Therefore, in order to ensure the operational stability of semiconductor devices, a technique for improving the heat dissipation characteristics of semiconductor devices must be employed.

A conventional semiconductor chip mounting structure is known where a semiconductor chip is flip-chip mounted by use of solder bumps with the electrode-formed surface of the semiconductor chip facing down. For example, the technique shown in FIG. 8 of Japanese Patent Application Laid-Open No. 2001-257288 is known as a technique for dissipating heat in a semiconductor device having a flip-chip mounted semiconductor chip. In this technique, a heat spreader is mounted on the rear surface of a semiconductor chip via a thermal interface material (hereinafter abbreviated as TIM) to thereby dissipate the heat generated by the semiconductor chip.

In conventional semiconductor devices, a flip-chip-mounted semiconductor chip is encapsulated with resin, so that the semiconductor chip makes contact with the encapsulating resin. The encapsulating resin in contact with the semiconductor chip is affected by the heat generated by the semiconductor chip and may cause a problem due to warpage.

### SUMMARY OF THE INVENTION

The present invention has been made in view of the foregoing problems, and it is a general purpose of the invention to provide a semiconductor device in which the effect of the heat generated by a flip-chip-mounted semiconductor chip on resin is suppressed.

An embodiment of the present invention relates to a semiconductor device. The semiconductor device includes: a substrate; a semiconductor chip which is mounted on the substrate with a front surface of the semiconductor chip facing downward; and a molding resin layer provided on a semiconductor chip-mounted surface of the substrate so as to be spaced apart from the semiconductor chip and to surround the semiconductor chip.

In this embodiment, the semiconductor chip does not make contact with the molding resin layer, so that the molding resin layer is less likely to be affected by the heat from the semiconductor chip.

In the above embodiment, an upper surface of the molding resin layer may be positioned higher than a rear surface of the semiconductor chip. In such a case, when a cooling member used to dissipate the heat from the semiconductor chip is bonded to the molding resin layer, the distance between the cooling member and the semiconductor chip is easily held constant.

In the above embodiment, the semiconductor device may further include: a cooling member which dissipates heat from the semiconductor chip; an adhesive layer which bonds the cooling member to the upper surface of the molding resin layer; and a thermal interface material layer which thermally connects the cooling member to the rear surface of the semiconductor chip. In such a case, the transfer of the heat generated by the semiconductor chip to the cooling member is facilitated through the thermal interface material layer, and therefore the heat is dissipated efficiently.

In the above embodiment, a recessed portion may be provided in the upper surface of the molding resin layer. In such a case, the prevention of the flow of an adhesive constituting the adhesive layer toward the outside of the molding resin layer is facilitated when the cooling member is bonded to the molding resin layer.

In the above embodiment, in a plane that is flush with the upper surface of the molding resin layer, the area of an opening of the recessed portion may be greater than the area of the upper surface of the molding resin layer. In such a case, the flow of the adhesive constituting the adhesive layer toward the recessed portion provided in the upper surface of the molding resin layer is facilitated when the cooling member is bonded to the molding resin layer.

In the above embodiment, the adhesive layer may be provided in the recessed portion. In such a case, the bonding area between the adhesive layer and the molding resin layer can be easily increased, so that the bonding strength between the adhesive layer and the molding resin layer can be easily improved.

In the above embodiment, an outflow passage which provides communication between the recessed portion and a side surface of the molding resin layer may be provided in the upper surface of the molding resin layer, wherein the outflow passage has a bottom portion positioned higher than a bottom portion of the recessed portion. In such a case, when the cooling member is bonded to the molding resin layer, the discharge of an excess amount of the adhesive constituting the adhesive layer to the side surface of the molding resin layer is facilitated when an inflow of the adhesive exceeds the capacity of the recessed portion.

Another embodiment of the present invention relates to a method for manufacturing a semiconductor device. The method for manufacturing a semiconductor device includes: flip-chip mounting a semiconductor chip on a substrate having a wiring pattern formed thereon, with a front surface of the semiconductor chip facing downward; and molding a molding resin layer onto a semiconductor chip-mounted surface of the substrate so as to be spaced apart from the semiconductor chip and to surround the semiconductor chip.

According to this embodiment, a semiconductor device is easily produced in which a semiconductor chip does not make contact with a molding resin layer.

It should be appreciated that any suitable combination of the aforementioned embodiments and/or constituting elements should be understood to be included within the scope of the invention for which protection is sought by the filing of the present patent application.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1A is a perspective view illustrating the schematic configuration of a semiconductor device according to embodiment 1;

FIG. 1B is a cross-sectional view illustrating a cross-sectional structure taken along the line A-A′ in FIG. 1A;

FIG. 2 is a cross-sectional view illustrating in more detail the structure of a substrate;

FIG. 3 is a flowchart showing the outline of a method for manufacturing the semiconductor device of embodiment 1;

FIG. 4A is a series of cross-sectional process diagrams showing a method for mounting a semiconductor chip of the semiconductor device of embodiment 1;

FIG. 4B is a series of cross-sectional process diagrams showing a method for mounting a semiconductor chip of the semiconductor device of embodiment 1;

FIG. 5A is a series of process diagrams showing a method for forming a molding resin layer of the semiconductor device of embodiment 1;

FIG. 5B is a series of process diagrams showing a method for forming a molding resin layer of the semiconductor device of embodiment 1;

FIG. 5C is a series of process diagrams showing a method for forming a molding resin layer of the semiconductor device of embodiment 1;

FIG. 6A is a series of process diagrams showing the method for forming the molding resin layer of the semiconductor device of embodiment 1;

FIG. 6B is a series of process diagrams showing the method for forming the molding resin layer of the semiconductor device of embodiment 1;

FIG. 7A is a series of process diagrams showing a method for bonding a lid of the semiconductor device of embodiment 1;

FIG. 7B is a series of process diagrams showing a method for bonding a lid of the semiconductor device of embodiment 1;

FIG. 8A shows a cross-sectional structure of a semiconductor device according to embodiment 2;

FIG. 8B shows a cross-sectional structure of a semiconductor device 12 according to embodiment 3;

FIG. 9 is a diagram illustrating a method for forming the molding resin layer by means of a heat curing apparatus having a simple structure;

FIG. 10A is a diagram showing the procedure for curing the molding resin layers of semiconductor devices by means of the heat curing apparatus; and

FIG. 10B is a diagram showing the procedure for curing the molding resin layers of semiconductor devices by means of only a molding apparatus.

### DETAILED DESCRIPTION OF THE INVENTION

The invention will now be described by reference to the preferred embodiments. This does not intend to limit the scope of the present invention, but to exemplify the invention.

Hereinafter, the preferred embodiments of the present invention will be described with reference to the accompanying drawings.

### Embodiment 1

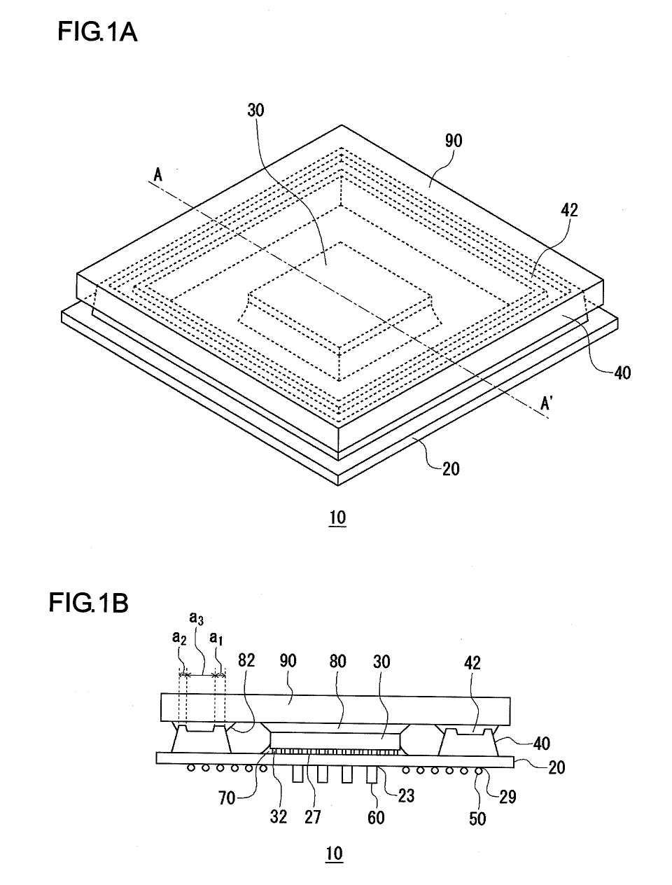

FIG. 1A is a perspective view illustrating the schematic configuration of a semiconductor device 10 according to embodiment 1. FIG. 1B is a cross-sectional view illustrating a cross-sectional structure taken along the line A-A′ in FIG. 1A. The semiconductor device 10 includes: a substrate 20; a semiconductor chip 30 which is flip-chip mounted on the substrate 20 with the front surface thereof facing downward; a molding resin layer 40 provided on the semiconductor chip-mounted surface of the substrate 20 so as to be spaced apart from the semiconductor chip 30 and to surround the semiconductor chip 30; and a lid 90 which is bonded to the rear surface of the semiconductor chip 30 through a TIM layer 80 and to the upper surface of the molding resin layer 40 through an adhesive layer 82.

Since the molding resin layer 40 is provided so as to be spaced apart from the semiconductor chip 30, the effect of the heat from the semiconductor chip 30 on the molding resin layer 40 can be suppressed. Therefore, any warpage of the molding resin layer 40 during temperature cycling can also be suppressed. Furthermore, since the molding resin layer 40 is provided so as to surround the semiconductor chip 30, the stiffness of the substrate 20 can be improved while the effect of the heat is suppressed.

The lid 90 acts as a cooling member for dissipating the heat from the semiconductor chip 30, it serves as a lid for closing the inner space surrounded by the molding resin layer 40, and it acts to protect the semiconductor chip 30. A material with good heat dissipation characteristics is selected as the material for the TIM layer 80. For example, X-23-7772-4 (product of Shin-Etsu Chemical Co., Ltd.) may be used. A material with good bonding characteristics and cushioning characteristics is selected as the material for the adhesive layer 82. For example, Sylgard 577 (product of TORAY industries, Inc.) may be used. The semiconductor device 10 of the present embodiment has a BGA (Ball Grid Array) type semiconductor package structure in which a plurality of solder balls 50 are arranged in an array on the rear surface of the substrate 20.

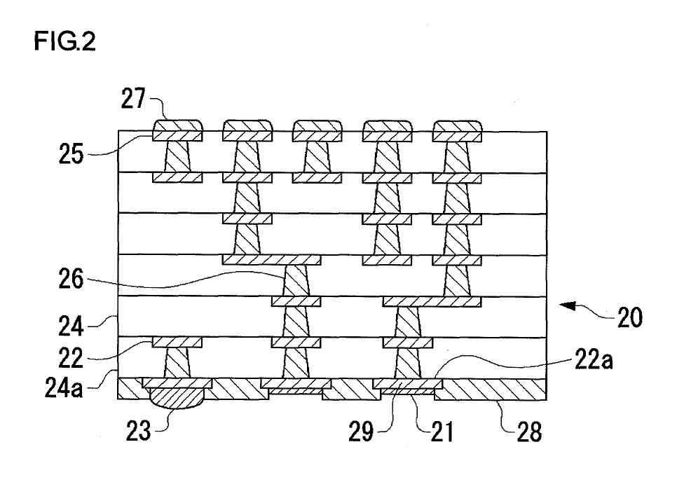

The substrate 20 of the present embodiment has a multilayer interconnection structure in which an interlayer insulating film and a wiring layer are alternately stacked. FIG. 2 is a cross-sectional view illustrating the structure of the substrate 20 in more detail. A plurality of wiring layers 22 are stacked with an interlayer insulating film 24 therebetween. Copper, for example, is employed to form the wiring layers 22. The wiring layers 22 of different levels are electrically connected through a via plug 26 provided in the interlayer insulating film 24. A solder resist film 28 composed of a resin material with excellent thermal resistance is formed around a wiring layer 22a on the rear surface of the substrate 20. Hence, a lowermost interlayer insulating film 24a is coated with the solder resist film 28 such that the solder is prevented from sticking to areas other than those areas desired when the substrate 20 is subjected to soldering. Furthermore, a plurality of ball lands 29 to which the solder balls 50 are bonded are arranged in an array on the rear surface of the substrate 20. The surface of each of the ball lands 29 is coated with an organic surface protection (OSP) coating material 21. Moreover, an electrode pad 23 made of tin (Sn), silver (Ag), or copper (Cu), or an alloy thereof is formed in the electrode portions on which a capacitor 60 is mounted. Furthermore, a plurality of electrode pads 25 made of nickel (Ni), lead (Pb), or gold (Au), or an alloy thereof formed by electrolytic plating are arranged in an array on the front surface of the substrate 20. The semiconductor chip is to be mounted on this front surface. A C4 (Controlled Collapse Chip Connection) bump 27 made of tin or lead, or an alloy thereof is provided on each of the electrode pads 25.

As described above, the substrate 20 of the present embodiment is a coreless substrate, and therefore the thickness thereof can be reduced to, for example, approximately 300 μm in a six-layer structure. By reducing the thickness of the substrate 20, the wiring resistance is reduced, so that an increase in the operational speed of the semiconductor device 10 can be achieved.

Returning to FIGS. 1A and 1B, each of the solder balls 50 is bonded to a corresponding one of the ball lands 29 provided on the rear surface of the substrate 20. Furthermore, the capacitor 60 is mounted on each of the electrode pads 23 provided on the rear surface of the substrate 20.

The semiconductor chip 30 such as an LSI is flip-chip mounted on the front surface of the substrate 20 with the front surface of the semiconductor chip 30 facing downward. More specifically, each solder bump 32 serving as an external electrode of the semiconductor chip 30 is soldered to a corresponding C4 bump 27 of the substrate 20. The gap between the semiconductor chip 30 and the substrate 20 is filled with an underfill 70. Changes in the gap between the substrate 20 and the semiconductor chip 30 caused by thermal expansion during temperature cycling may cause stress on the C4 bumps 27, however this stress can be reduced by the provision of the underfill 70 between the semiconductor chip 30 and the substrate 20.

The upper surface of the molding resin layer 40 is positioned higher than the rear surface of the semiconductor chip 30, so that the position of the lid 90 depends on the position of the upper surface of the molding resin layer 40. Therefore, the distance between the rear surface of the semiconductor chip 30 and the lid 90 can be kept constant, so that heat is uniformly transferred to the lid 90 from the rear surface of the semiconductor chip 30 through the TIM layer 80. In this manner, the heat dissipation characteristics of the semiconductor device 10 are improved.

In FIG. 1B, the thickness of the adhesive layer 82 is exaggerated in order to emphasize the presence of the adhesive layer 82 located between the molding resin layer 40 and the lid 90. In practice, when the lid 90 is bonded to the molding resin layer 40 through the adhesive layer 82, the lid 90 is bonded while being pressed against the molding resin layer 40 to the extent that no influence is exerted on the semiconductor device 10. Therefore, the actual thickness of the adhesive layer 82 is very small and uniform, so that the distance between the rear surface of the semiconductor chip 30 and the lid 90 is kept constant. This is also the case in the other figures.

When the lid 90 is bonded to the molding resin layer 40 through the adhesive layer 82, an uncured adhesive constituting the adhesive layer 82 is squeezed out between the lid 90 and the molding resin layer 40 by pressing the lid 90 against the molding resin layer 40. However, by providing a groove 42 in the upper surface of the molding resin layer 40, the adhesive that is squeezed out is allowed to flow into the groove 42, whereby the adhesive is prevented from flowing outside of the molding resin layer 40.

Furthermore, the adhesive having flowed into the groove 42 is solidified to form the adhesive layer 82 in the groove 42. In this case, the bonding area between the adhesive layer 82 and the molding resin layer 40 is larger than that in the case in which the groove 42 is not provided. Accordingly, the bonding strength between the adhesive layer 82 and the molding resin layer 40 increases, so that any exfoliation of the adhesive layer 82 from the molding resin layer 40 caused by thermal expansion during temperature cycling can be prevented.

Preferably, the depth of the groove 42 provided in the upper surface of the molding resin layer 40 is in the range of 0.2 mm to 0.3 mm. In order to improve the bonding strength between the adhesive layer 82 and the molding resin layer 40, the groove 42 must be filled with the adhesive layer 82. In other words, the adhesive having flowed into the groove 42 must be firmly bonded to the adhesive between the lid 90 and the upper surface of the molding resin layer 40. When the depth of the groove 42 is greater than 0.3 mm, the groove 42 may not be fully filled with the adhesive. When the depth is smaller than 0.2 mm, a bonding strength sufficient for eliminating the effect of thermal expansion during temperature cycling may not be obtained since the bonding area has decreased, or the adhesive may not be prevented from flowing outside of the molding resin layer 40.

In the present embodiment, the groove 42 is provided over the entire circumference of the upper surface of the molding resin layer 40. However, the groove 42 may be provided not in the entire circumference of the upper surface of the molding resin layer 40, but instead in each of the four sides of the upper surface of the molding resin layer 40, so long as this does not cause any problems with regard to improving the bonding strength between the adhesive layer 82 and the molding resin layer 40 and does not prevent the adhesive from flowing outside of the molding resin layer 40.

In a plane that is flush with the upper surface of the molding resin layer 40, the area a3 of the opening of the groove 42 is greater than the area of the upper surface of the molding resin layer 40. As shown in FIG. 1B, the area of the upper surface of the molding resin layer 40 is the sum of the area al of its inner upper surface on the inner side of the groove 42 and the area a2 of its outer upper surface on the outer side of the groove 42. Accordingly, the flow of the adhesive applied to the upper surface of the molding resin layer 40 toward the groove 42 is actually facilitated in comparison to the case in which the area a3 of the opening of the groove 42 is smaller than the area of the upper surface of the molding resin layer 40. Moreover, since the area of the upper surface of the molding resin layer 40 facing the lid 90 is small, the effect of any warpage of the molding resin layer 40 caused by thermal expansion during temperature cycling is suppressed.

Preferably, the molding resin layer 40 covers the substrate 20 such that an area corresponding to the area outside the outermost solder balls 50 of the plurality of the solder balls 50 arranged in an array is also covered. In this manner, the strength of the substrate 20 is improved through the molding resin layer 40, so that any warpage of the substrate 20 is suppressed. As described above, the molding resin layer 40 also serves as a reinforcing material for the substrate 20, and therefore the overall strength of the semiconductor device 10 can be ensured even when the thickness of the substrate 20 is further reduced.

The capacitors 60 are connected to the rear surface of the substrate 20 at positions directly below the semiconductor chip 30. Hence, the wiring path from the semiconductor chip 30 to each of the capacitors 60 can be reduced, and as such, a reduction in wiring resistance can be achieved. It should be appreciated that the mounting position of each of the capacitors 60 is not limited to a position on the rear surface of the substrate 20 directly below the semiconductor chip 30. For example, the capacitors 60 may be mounted on the rear surface of the substrate 20 at positions outside of the area directly below the semiconductor chip 30, so long as the wiring path can be sufficiently reduced. Alternatively, the capacitors 60 may be mounted on the front surface of the substrate 20, so long as the wiring path can be sufficiently reduced.

### Method for Manufacturing a Semiconductor Device

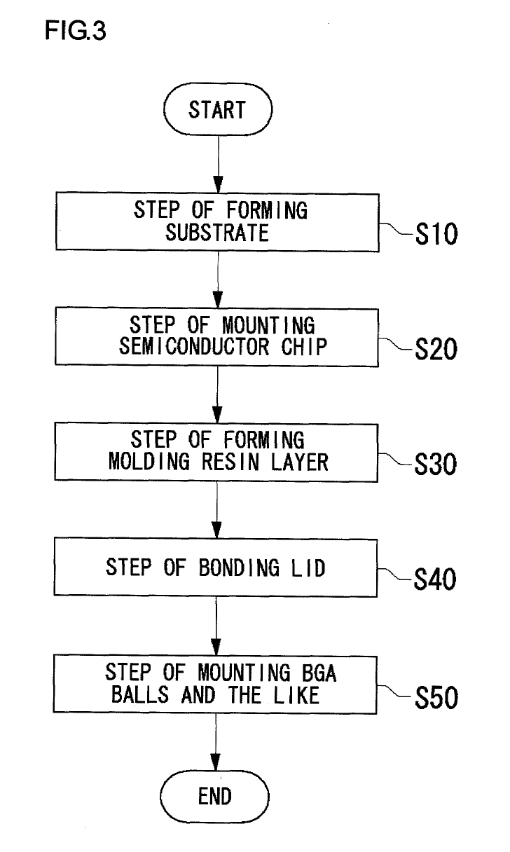

FIG. 3 is a flowchart showing the outline of a method for manufacturing the semiconductor device detailed in embodiment 1. First, a substrate having a multilayer interconnection structure is formed (S10), and a semiconductor chip is mounted on the substrate (S20). Subsequently, a molding resin layer is formed around the semiconductor chip so as to be spaced apart from the semiconductor chip (S30). Then, a lid is bonded to the rear surface of the semiconductor chip through a TIM layer and to the upper surface of the molding resin layer through an adhesive layer (S40). Finally, solder balls, capacitors, and the like are mounted on the rear surface of the substrate (S50).

When the substrate is formed (S10), the multilayer interconnection structure shown in FIG. 2 is formed by means of a generally used method such a damascene process. Similarly, in S50, the solder balls and capacitors may be mounted by means of a general method, well known to those skilled in the art. Hereinafter, a detailed description will be given of a method for mounting the semiconductor device (S20), a method for forming the molding resin layer (S30), and a method for bonding the lid (S40).

### 1. Method for Mounting a Semiconductor Chip

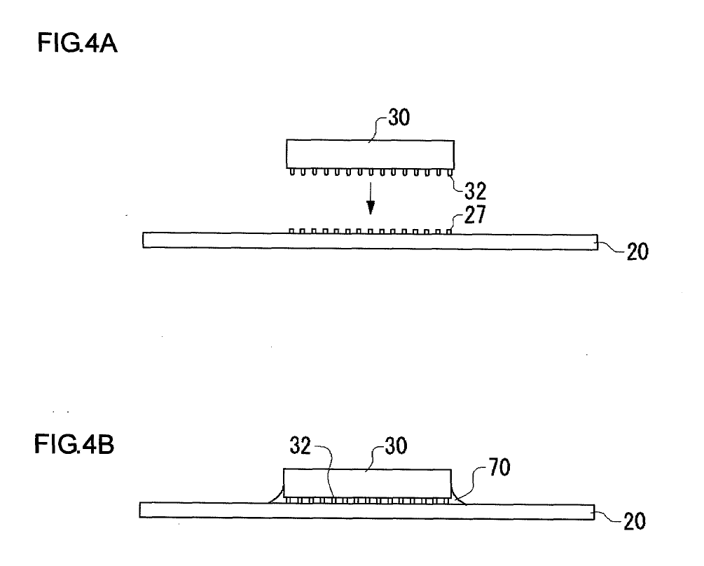

FIG. 4 is a series of cross-sectional process diagrams showing the method for mounting the semiconductor chip 30 of the semiconductor device 10 detailed in embodiment 1.

First, as shown in FIG. 4A, each of the solder bumps 32 is soldered to a corresponding C4 bump 27 with the external electrode terminal-mounted surface of the semiconductor chip 30 facing downward, whereby the semiconductor chip 30 is flip-chip mounted.

Subsequently, as shown in FIG. 4B, the underfill 70 is filled into the gap between the semiconductor chip 30 and the substrate 20.

By following the above steps, the semiconductor chip 30 is flip-chip mounted on the substrate 20 with the stress generated in the solder bonding portions dispersed through the underfill 70.

### 2. Method for Forming a Molding Resin Layer

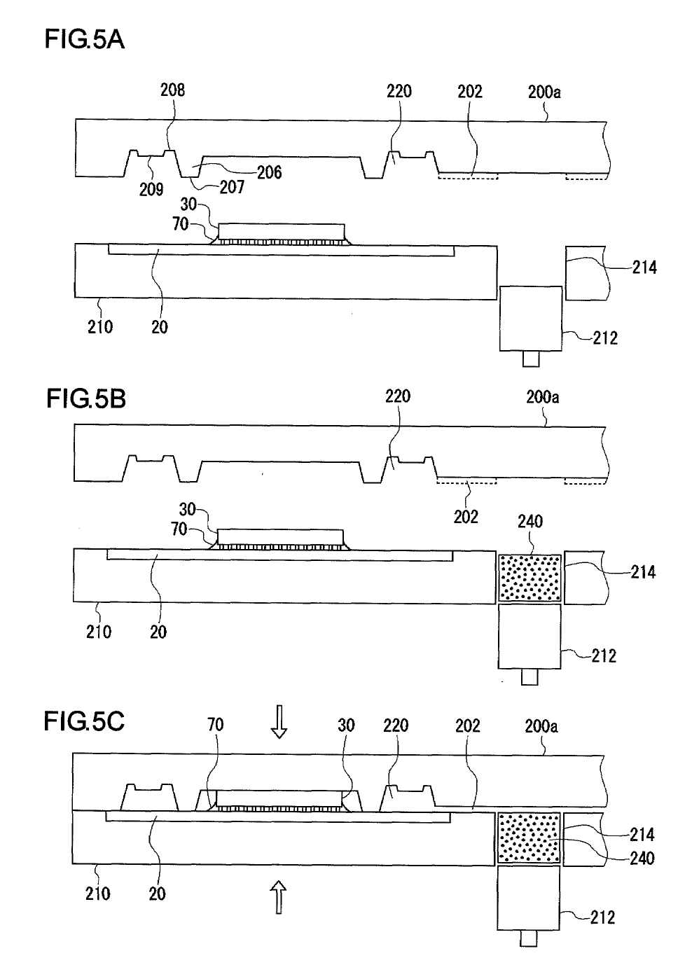

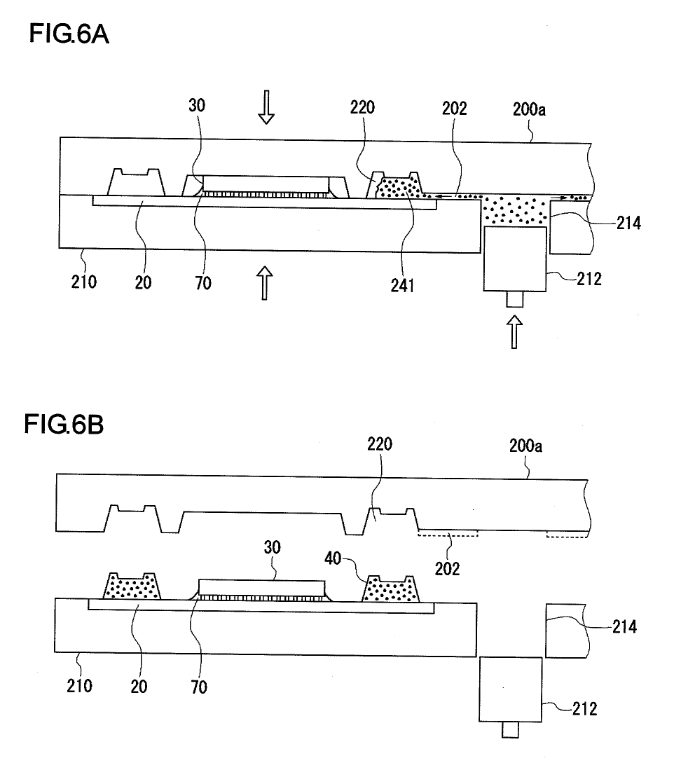

FIGS. 5 and 6 show a series of process diagrams showing the method for forming the molding resin layer of the semiconductor device 10 detailed in embodiment 1.

First, a description will be given of the configuration of an upper mold 200a and a lower mold 210 used in the method for forming the molding resin layer. The upper mold 200a has a runner 202 serving as a flow passage for a molten encapsulation resin. The runner 202 has an opening which opens into a cavity 220 which is formed when the upper mold 200a and the lower mold 210 are brought together.

The upper mold 200a has a downwardly protruding portion 206 for forming the molding resin layer which is to be provided around the semiconductor chip 30 so as to be spaced apart from the semiconductor chip 30. A bottom surface 207 of the protruding portion 206 comes into contact with the substrate 20 when the molding resin layer is molded, and as such, the resin is prevented from flowing to the inner side of the protruding portion 206. In this manner, the molding resin layer 40 can be formed so as to be spaced apart from the semiconductor chip 30.

A molding surface 208 for forming the molding resin layer 40 is provided on the upper mold 200a. The upper surface of the molding resin layer 40 is formed by the upper surface of the molding surface 208. A downwardly protruding portion 209 for forming the groove 42 is provided on the upper surface of the molding surface 208.

Furthermore, the lower mold 210 has a pot 214 having a plunger 212 which is formed so as to be reciprocally movable.

The upper mold 200a and the lower mold 210 described above are used, and the substrate 20 having the semiconductor chip 30 mounted thereon is placed on the lower mold 210 as shown in FIG. 5A.

Next, as shown in FIG. 5B, a solidified resin tablet 240 serving as the material for forming the molding resin layer is charged into the pot 214.

Next, as shown in FIG. 5C, the upper mold 200a and the lower mold 210 are clamped together.

Subsequently, the resin tablet 240 is heated and melted. In this state, the plunger 212 is pressed into the pot 214 to thereby introduce a liquid resin 241 into the cavity 220, as shown in FIG. 6(A). After the space formed between the upper mold 200a and the substrate 20 is filled with the resin 241, heat treatment is performed for a predetermined period of time, and the encapsulating resin 241 is solidified.

Next, as shown in FIG. 6B, the upper mold 200a is separated from the lower mold 210, and the substrate 20 having the molding resin layer 40 formed thereon is removed.

### 3. Method for Bonding a Lid

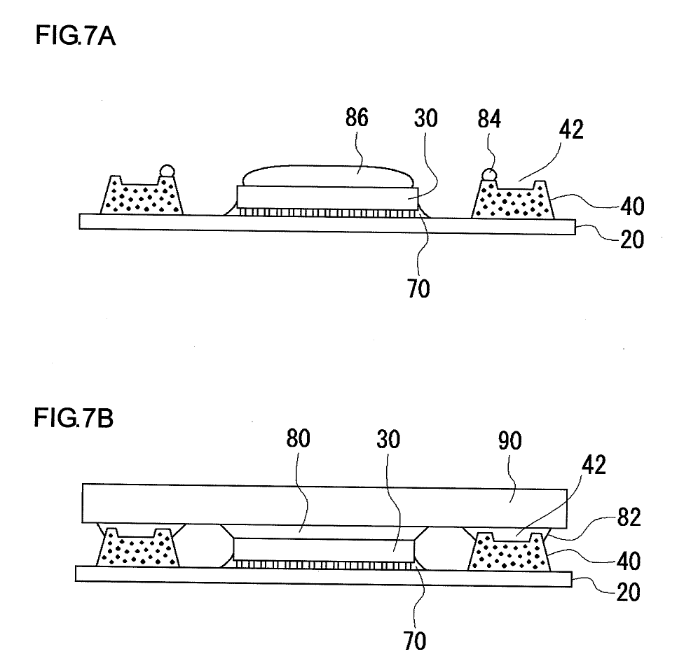

FIG. 7 is a series of process diagrams showing the method for bonding the lid of the semiconductor device 10 detailed in embodiment 1.

First, as shown in FIG. 7A, an adhesive 84 is applied to the upper surface of the molding resin layer 40. Specifically, the adhesive 84 is applied to the upper surface of the molding resin layer 40 on the inner side of the groove 42 provided in the upper surface. Hence, when the lid 90 is pressed against the molding resin layer 40, the adhesive 84 flows into the groove 42, and as such, the adhesive 84 is prevented from flowing outside of the molding resin layer 40. Furthermore, a TIM 86 is applied to the rear surface of the semiconductor chip 30.

Next, as shown in FIG. 7B, the lid 90 is pressed against the molding resin layer 40. Thereafter, the adhesive 84 and the TIM 86 are dried, whereby the adhesive layer 82 and the TIM layer 80 are formed.

The adhesive 84 is applied to the upper surface of the molding resin layer 40 such that, in order to prevent an inner space surrounded by the molding resin layer 40 and the lid 90 from being sealed, a space serving as a vent hole for providing communication between the inner space and the outside space is provided in the adhesive layer 82. More specifically, the adhesive 84 is not applied to the entire circumference of the upper surface of the molding resin layer 40, but is instead applied so that a portion of the upper surface is not coated with the adhesive 84, thereby forming the space. In the present embodiment, the groove 42 is provided in the upper surface of the molding resin layer 40. Hence, the adhesive 84 flows into the groove 42, and the uncoated portion is less likely to be filled with any adhesive 84 that has been squeezed out. Therefore, the groove 42 also has the effect of ensuring the formation of the vent hole provided in the adhesive layer 82.

By providing the vent hole in the adhesive layer 82, the semiconductor device can be prevented from being damaged when air in the inner space expands during heat resistance testing. The vent hole may be formed by providing a groove for providing communication between the inner space and the outside space in a surface of the lid 90 which faces the molding resin layer 40 or by providing a similar groove in the upper surface of the molding resin layer 40.

### Embodiment 2

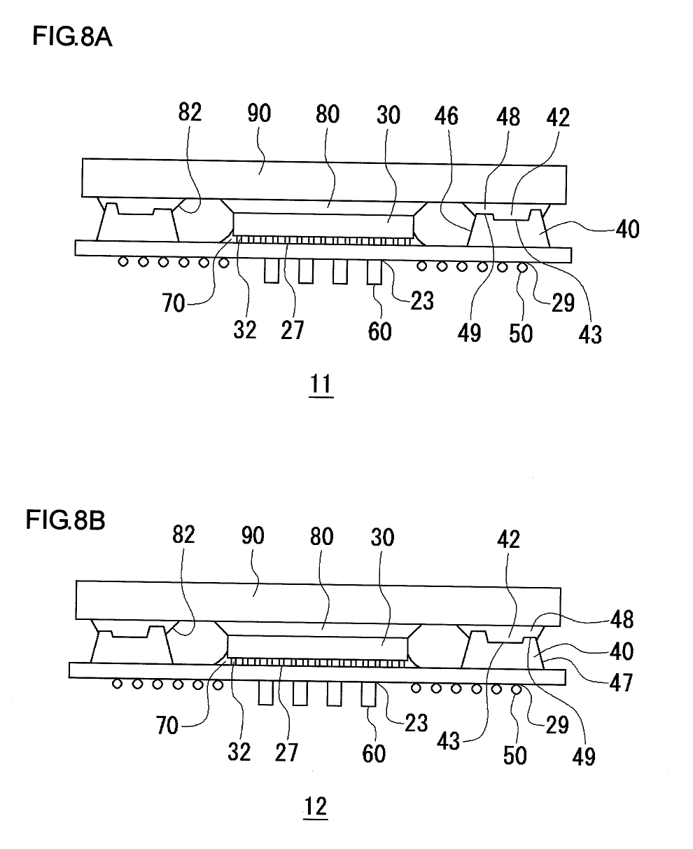

FIG. 8A shows a cross-sectional structure of a semiconductor device 11 according to embodiment 2. In the description of the semiconductor device 11 according to embodiment 2, a description of the configuration similar to that of the semiconductor device 10 according to embodiment 1 will be omitted as appropriate. A description is given below of the configuration that differs from that of the semiconductor device 10 according to embodiment 1.

In the semiconductor device 11, an outflow passage 48 for providing communication between the groove 42 and an inner side surface 46 of the molding resin layer 40 is provided in the inner upper surface of the molding resin layer 40 which is located on the inner side of the groove 42. The outflow passage 48 is provided such that a bottom portion 49 of the outflow passage 48 is positioned higher than a bottom portion 43 of the groove 42. In this manner, when the lid 90 is pressed against the molding resin layer 40, an excess amount of the adhesive can be discharged to the inside of the molding resin layer 40 through the outflow passage 48 when the amount of the adhesive flowing into the groove 42 exceeds the capacity of the groove 42. Accordingly, the adhesive can be prevented from flowing outside of the molding resin layer 40.

A method for manufacturing the semiconductor device 11 according to embodiment 2 is similar to the method in embodiment 1. However, in the method for manufacturing the semiconductor device 11 according to embodiment 2, a different upper mold 200a is used in the encapsulating resin forming step shown in FIGS. 5 and 6. Specifically, this upper mold 200a has another downwardly protruding portion which is joined to the protruding portion 209 and to the inner side surface of the molding surface 208. In this instance, the bottom surface of the other protruding portion is positioned higher than the bottom surface of the protruding portion 209.

### Embodiment 3

FIG. 8B shows a cross-sectional structure of a semiconductor device 12 according to embodiment 3. In the description of the semiconductor device 12 according to embodiment 3, a description of the configuration similar to that of the semiconductor device 11 according to embodiment 2 will be omitted as appropriate. A description is given below of the configuration that differs from that of the semiconductor device 11 according to embodiment 2.

In embodiment 2, the adhesive is prevented from flowing outside of the molding resin layer 40 by the provision of the outflow passage 48. However, in some manufacturing methods, it is convenient to discharge the adhesive to the outside of the molding resin layer 40 rather than to the inside. Furthermore, when the lid 90 is pressed against the molding resin layer 40, if the molding resin layer 40 is located close to the semiconductor chip 30, the TIM 86 applied to the rear surface of the semiconductor chip 30 may come into contact with the adhesive 84 applied to the upper surface of the molding resin layer 40. When the contact between the TIM 86 and the adhesive 84 does not cause any problems, the adhesive 84 may be discharged to the inner side of the molding resin layer 40. However, when the contact causes problems, it is desirable to discharge the adhesive 84 to the outside of the molding resin layer 40. Embodiment 3 provides a desirable configuration in such a case.

In the semiconductor device 12, the outflow passage 48 for providing communication between the groove 42 and an outer side surface 47 of the molding resin layer 40 is provided in the outer upper surface of the molding resin layer 40 which is located on the outer side of the groove 42. The outflow passage 48 is provided such that the bottom portion 49 of the outflow passage 48 is positioned higher than the bottom portion 43 of the groove 42. In this configuration, the lid 90 is pressed against the molding resin layer 40. Then, an excess amount of the adhesive can be discharged to the outside of the molding resin layer 40 through the outflow passage 48 when the amount of the adhesive flowing into the groove 42 exceeds the capacity of the groove 42. Accordingly, the adhesive can be prevented from flowing inside the molding resin layer 40.

A method for manufacturing the semiconductor device 12 according to embodiment 3 is similar to the method detailed in embodiment 1. However, in the method for manufacturing the semiconductor device 12 according to embodiment 3, a different upper mold 200a is used in the encapsulating resin forming step shown in FIGS. 5 and 6. Specifically, this upper mold 200a has another downwardly protruding portion which is joined to the protruding portion 209 and to the outer side surface of the molding surface 208. In this instance, the bottom surface of the other protruding portion is positioned higher than the bottom surface of the protruding portion 209.

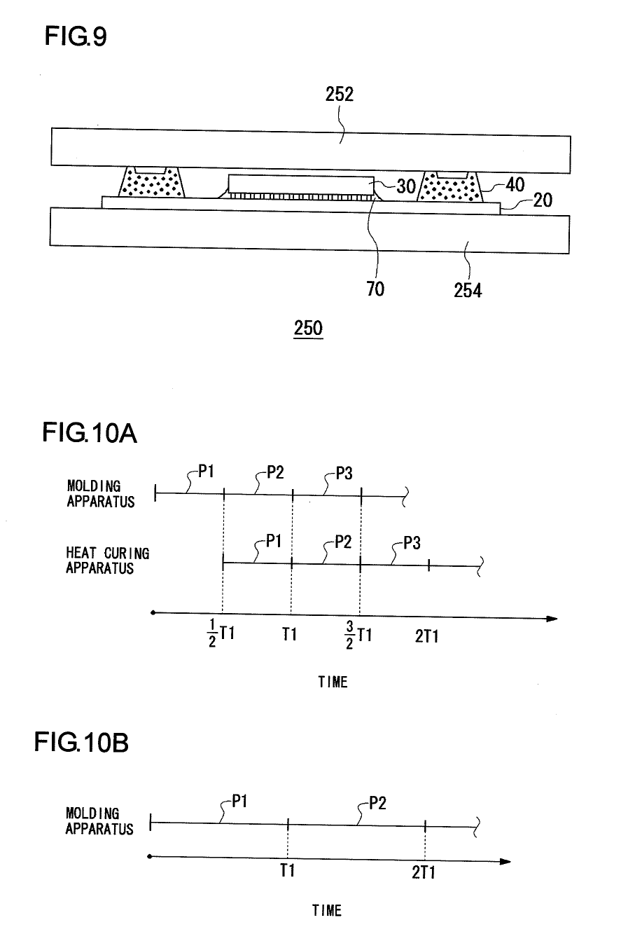

It should be appreciated that the method for packaging the semiconductor device using a molding resin is not limited to a method in which the molding resin introduced into the cavity is heat-cured using the molding apparatus shown in FIGS. 5 and 6. For example, the heat curing does not need to be completed in the molding apparatus. The heat curing treatment may be continued using a heat curing apparatus 250 having a simple structure, as shown in FIG. 9, and be completed in the heat curing apparatus 250.

Such a heat curing apparatus 250 has a lower-side plate 254, an upper-side plate 252, a pressurizing means (not shown), and a heating means (not shown). The lower-side plate 254 has a flat surface which comes into contact with the lower surface of the substrate 20 of the semiconductor device. The upper-side plate 252 has a flat surface which comes into contact with the upper surface of the molding resin layer 40 of the semiconductor device. The heating means, such as a heater, is provided in each of the lower-side plate 254 and the upper-side plate 252, and the lower-side plate 254 and the upper-side plate 252 are heated to the curing temperature of the molding resin layer 40 used in the semiconductor device by means of the heating means. The semiconductor device held between the lower-side plate 254 and the upper-side plate 252 is pressurized at a predetermined pressure by means of the pressurizing means.

By using the heat curing apparatus 250 described above, the curing of the molding resin layer 40 can be completed while the semiconductor device is held between the lower-side plate 254 and the upper-side plate 252 heated to a predetermined temperature to suppress the occurrence of warpage. The contact area between the molding resin layer 40 and the upper-side plate 252 may be increased by providing a protruding portion in a flat surface of the upper-side plate 252 which comes into contact with the upper surface of the molding resin layer 40. The protruding portion is brought into engagement with a recessed portion provided in the upper surface of the molding resin layer 40.

With reference to FIG. 10A, a description is given of the procedure for curing the molding resin layer of the semiconductor device by using the heat-curing apparatus described above. Semiconductor devices having a molding resin layer to be cured are labeled with P1, P2, P3, and so on. The time required for curing at a predetermined temperature is defined as standard curing time T1. First, heat curing is performed on the semiconductor device P1 in the molding apparatus for one-half of T1 (being ½×T1). Subsequently, the semiconductor device P1 is placed in the heat curing apparatus, and a next semiconductor device P2 having a molding resin layer to be cured is placed in the molding apparatus. Then, heat curing is performed on the semiconductor device P1 in the heat curing apparatus for one-half of T1 (being ½×T1), and heat curing is performed on the semiconductor device P2 in the molding apparatus for one-half of T1 (being ½×T1). In other words, heat curing is performed on one semiconductor device in the molding apparatus and at the same time is performed on a different semiconductor device in the heat curing apparatus.

In this manner, as shown in FIG. 10B, the time required for curing the molding resin layers can be reduced to one-half of the time required for sequentially curing the molding resin layers of the semiconductor devices using only the molding apparatus, and as such, an improvement in the manufacturing productivity of the semiconductor devices can be achieved. Since the structure of the heat curing apparatus is simpler than that of the molding apparatus, the heat curing apparatus is relatively less expensive. Therefore, the investment costs required can be reduced when compared to the case in which two molding apparatus are employed. In FIG. 10A, the time required for transferring the semiconductor devices P1, P2, P3, . . . from the molding apparatus to the heat curing apparatus is omitted for ease of understanding.

More specifically, when a conventional type epoxy resin with T1=60 seconds is used as the resin to be molded, the work time for one semiconductor device in the heat curing treatment can be reduced to about 30 seconds. In addition, even when the required T1 is longer than that of a conventional resin, the work time required for the heat curing treatment can be halved. For example, when T1 is 120 seconds, the work time required for one semiconductor device in the heat curing treatment can be reduced to about 60 seconds.

In the lower-side plate 254 and/or the upper-side plate 252 of the heat curing apparatus, a surface which comes into contact with the semiconductor device may be formed into a shape for correcting warpage according to the warpage characteristics of the semiconductor device. In this manner, any warpage of the semiconductor device can be further suppressed.

In the above curing procedure for the molding resin layers, T1 is divided into two periods. However, when two or more heat curing apparatuses are used, T1 may be divided into three or more periods, and the heat curing treatment may be performed simultaneously in three or more apparatuses, with the apparatuses including the molding apparatus and a plurality of heat curing apparatuses.

It should be appreciated that the present invention is not limited to the embodiments described above. Various modifications such as changes in design may be made based on the knowledge of those skilled in the art, and such modifications may fall within the scope of the invention.

For example, in each of the embodiments described above, the substrate 20 has a coreless multilayer interconnection structure. However, the technical concept of the present invention is applicable to a multilevel interconnection substrate having a core.

Furthermore, in each of the embodiments described above, a BGA type semiconductor package is employed, however the invention is not limited thereto. For example, a PGA (Pin Grid Array) type semiconductor package having pin-shaped lead terminals or an LGA (Land Grid Array) type semiconductor package having electrodes arranged in an array may instead be employed.

What is claimed is:

1. A semiconductor device comprising:
a substrate;
a semiconductor chip which is mounted on the substrate with a front surface of the semiconductor chip facing downward; and
a molding resin layer provided on a semiconductor chip-mounted surface of the substrate so as to be spaced apart from the semiconductor chip and to surround the semiconductor chip.

2. The semiconductor device according to claim 1, wherein an upper surface of the molding resin layer is positioned higher than a rear surface of the semiconductor chip.

3. The semiconductor device according to claim 1, wherein a recessed portion is provided in an upper surface of the molding resin layer.

4. The semiconductor device according to claim 2, wherein a recessed portion is provided in the upper surface of the molding resin layer.

5. The semiconductor device according to claim 3, wherein, in a plane that is flush with the upper surface of the molding resin layer, an area of an opening of the recessed portion is greater than an area of the upper surface of the molding resin layer.

6. The semiconductor device according to claim 4, wherein, in a plane that is flush with the upper surface of the molding resin layer, an area of an opening of the recessed portion is greater than an area of the upper surface of the molding resin layer.

7. The semiconductor device according to claim 1, further comprising:
a cooling member which dissipates heat from the semiconductor chip;
an adhesive layer which bonds the cooling member to an upper surface of the molding resin layer; and
a thermal interface material layer which thermally connects the cooling member to a rear surface of the semiconductor chip.

8. The semiconductor device according to claim 2, further comprising:
a cooling member which dissipates heat from the semiconductor chip;
an adhesive layer which bonds the cooling member to the upper surface of the molding resin layer; and
a thermal interface material layer which thermally connects the cooling member to the rear surface of the semiconductor chip.

9. The semiconductor device according to claim 7, wherein the adhesive layer is provided in a recessed portion provided in an upper surface of the molding resin layer.

10. The semiconductor device according to claim 8, wherein the adhesive layer is provided in a recessed portion provided in an upper surface of the molding resin layer.

11. The semiconductor device according to claim 3, wherein:
an outflow passage which provides communication between the recessed portion and a side surface of the molding resin layer is provided in the upper surface of the molding resin layer; and
the outflow passage has a bottom portion positioned higher than a bottom portion of the recessed portion.

12. The semiconductor device according to claim 4, wherein:
an outflow passage which provides communication between the recessed portion and a side surface of the molding resin layer is provided in the upper surface of the molding resin layer; and
the outflow passage has a bottom portion positioned higher than a bottom portion of the recessed portion.

13. The semiconductor device according to claim 5, wherein:
an outflow passage which provides communication between the recessed portion and a side surface of the molding resin layer is provided in the upper surface of the molding resin layer; and
the outflow passage has a bottom portion positioned higher than a bottom portion of the recessed portion.

14. A method for manufacturing a semiconductor device comprising:
flip-chip mounting a semiconductor chip on a substrate having a wiring pattern formed thereon, with a front surface of the semiconductor chip facing downward; and
molding a molding resin layer onto a semiconductor chip-mounted surface of the substrate so as to be spaced apart from the semiconductor chip and to surround the semiconductor chip.

15. The method for manufacturing a semiconductor device according to claim 14, wherein molding a molding resin layer
comprises providing a recessed portion in an upper surface of the molding resin layer.
